(19) United States
(12) Patent Application Publication
(10) Pub. No.: US 2026/0089861 A1
(43) Pub. Date: Mar. 26, 2026

(54) CABLE, DISPLAY DEVICE INCLUDING THE SAME AND METHOD FOR MANUFACTURING THE SAME

(71) Applicant: SAMSUNG ELECTRONICS CO., LTD., Suwon-si (KR)

(72) Inventors: Sunkyoung KIM, Suwon-si (KR); Seongjin YUN, Suwon-si (KR)

(73) Assignee: SAMSUNG ELECTRONICS CO., LTD., Suwon-si (KR)

(21) Appl. No.: 19/309,124

(22) Filed: Aug. 25, 2025

Related U.S. Application Data
(63) Continuation of application No. PCT/KR2025/011625, filed on Aug. 4, 2025.

(30) Foreign Application Priority Data
Sep. 24, 2024 (KR) 10-2024-0128982

(51) Int. Cl. H05K 5/02

(52) U.S. Cl. CPC H05K 5/0247

(57) ABSTRACT

A display device may include: a chassis assembly; a display panel on the chassis assembly; a circuit board assembly electrically connected to the display panel; and at least one cable configured to electrically connect the display panel or the circuit board assembly, wherein the at least one cable includes: a cable body including a connection terminal; and a pair of fixing portions respectively connected to two opposite ends of the cable body and configured to be at least partially separated from the corresponding end of the cable body by cutting, and wherein each of the fixing portions includes: a fixing portion body connected to the cable body and configured to be at least partially separated from the cable body by cutting, the fixing portion body including a fixing recess; and a cutting portion including at least one perforation line extending by a predetermined distance along a connecting portion between the fixing portion body and the cable body.

### CROSS-REFERENCE TO RELATED APPLICATIONS

This application is a by-pass continuation application of International Application No. PCT/KR2025/011625, filed on Aug. 4, 2025, which is based on and claims priority to Korean Patent Application No. 10-2024-0128982, filed on Sep. 24, 2024, in the Korean Intellectual Property Office, the disclosures of which are incorporated by reference herein in their entireties.

### BACKGROUND

### 1. Field

Various embodiments of the disclosure relate to a cable, a display device including the same, and a method for manufacturing the same.

### 2. Description of Background Art

A display device is an output device that converts electrical information into visual information and presents it to the user. The display device may include not only televisions and monitors, but also portable devices such as notebook personal computers (PCs), smartphones, and tablet PCs.

The display device may include a self-luminous display panel, such as an organic light emitting diode (OLED), or a light receiving display panel, such as a liquid crystal display (LCD).

A display device that includes a light receiving display panel may also include a backlight unit that provides light to the display panel. The backlight unit may be an edge-type backlight unit in which a light source is disposed on at least one side of the display panel, or a direct-type backlight unit in which a light source is disposed at the rear of the display panel.

A display device may include various circuit boards for operating the display device. The circuit boards may be connected to each other to transmit data, signals, or power. For example, the circuit boards may be connected to each other by electric wires, a flexible flat cable (FFC), or a flexible printed circuit board (FPCB).

The above-described information may be provided as related art for the purpose of helping understanding of the disclosure. No claim or determination is made as to whether any of the foregoing is applicable as prior art in relation to the disclosure.

### SUMMARY

According to an aspect of the disclosure, a display device may include: a chassis assembly; a display panel on the chassis assembly; a circuit board assembly electrically connected to the display panel; and at least one cable configured to electrically connect the display panel or the circuit board assembly, wherein the at least one cable includes: a cable body including a connection terminal; and a pair of fixing portions respectively connected to two opposite ends of the cable body and configured to be at least partially separated from the corresponding end of the cable body by cutting, and wherein each of the fixing portions includes: a fixing portion body connected to the cable body and configured to be at least partially separated from the cable body by cutting, the fixing portion body including a fixing recess; and a cutting portion including at least one perforation line extending by a predetermined distance along a connecting portion between the fixing portion body and the cable body, and wherein the fixing portion body is separable from the cable body along the cutting portion in a case where the at least one cable is being connected to the display panel or the circuit board assembly.

According to an aspect of the disclosure, a cable for electrical connection of an electronic component may include: a cable body including a connection terminal; and a pair of fixing portions respectively connected to two opposite ends of the cable body and configured to be at least partially separated from the first end of the cable body by cutting, wherein each of the fixing portions includes: a fixing portion body connected to the cable body and configured to be at least partially separated from the cable body by cutting, the fixing portion body including a fixing recess; and a cutting portion including at least one perforation line extending by a predetermined distance along a connecting portion between the fixing portion body and the cable body, wherein the fixing portion body is separable from the cable body along the cutting portion in a case where the cable is being connected to the electronic component.

According to an aspect of the disclosure, a method for manufacturing a display device may include: loading a cable onto a cable tray by: inserting a first fixing protrusion of the cable tray into a first fixing recess of a first fixing portion of the cable, wherein the first fixing portion is connected to a first end of a cable body of the cable, and the first fixing portion is configured to be at least partially separated from the first end of the cable body by cutting; and inserting a second fixing protrusion of the cable tray into a second fixing recess of a second fixing portion of the cable, wherein the second fixing portion is connected to a second end of the cable body of the cable, and the second fixing portion is configured to be at least partially separated from the second end of the cable body by cutting; separating at least a portion of the first fixing portion or at least a portion of the second fixing portion of the cable loaded on the cable tray; and connecting, after the separating at least the portion of the first fixing portion or at least the portion of the second fixing portion, the cable to an electronic component of the display device.

The disclosure is not limited to the foregoing example embodiments, and various modifications or changes may rather be made to embodiments of the disclosure without departing from the spirit and scope of the disclosure.

### BRIEF DESCRIPTION OF DRAWINGS

FIG. 1 is a perspective view illustrating a display device according to an embodiment of the disclosure;

FIG. 2 is an exploded perspective view illustrating a display device according to an embodiment of the disclosure;

FIG. 3 is a rear view illustrating a display rear chassis according to an embodiment of the disclosure;

FIG. 4 is a plan view illustrating an end portion of a cable according to an embodiment of the disclosure;

FIG. 5 is a vertical cross-sectional view illustrating a cable according to an embodiment of the disclosure;

FIG. 6 is a plan view illustrating an end portion of a cable according to an embodiment of the disclosure;

FIG. 7 is a plan view illustrating an end portion of a cable according to an embodiment of the disclosure;

FIG. 8 is a plan view illustrating an end portion of a cable according to an embodiment of the disclosure;

FIG. 9 is a plan view illustrating a plurality of cables connected, according to an embodiment of the disclosure;

FIG. 10 is a perspective view illustrating a plurality of cables loaded on a cable tray according to an embodiment of the disclosure;

FIG. 11 is a perspective view illustrating a plurality of cables loaded on a cable tray according to an embodiment of the disclosure;

FIG. 12 is a perspective view illustrating a plurality of cables loaded on a cable tray according to an embodiment of the disclosure;

FIG. 13 is a plan view illustrating a plurality of cables loaded on a cable tray according to an embodiment of the disclosure; and

FIG. 14 is a flowchart illustrating a method for manufacturing a display device according to an embodiment of the disclosure.

Reference may be made to the accompanying drawings in the following description, and specific examples that may be practiced are shown as examples within the drawings. Other examples may be utilized and structural changes may be made without departing from the scope of the disclosure.

### DETAILED DESCRIPTION

An electronic device according to embodiments of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

Example embodiments of the disclosure and terms used in the disclosure are not intended to limit embodiments of the disclosure, and the disclosure should be understood to include various modifications, equivalents, and substitutes of the example embodiments. With regard to the description of the drawings, similar reference numerals may be used to refer to similar or related elements. It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry.” A module may be a single integral component, or a minimum unit or part thereof, adapted to perform one or more functions. For example, according to an embodiment, the module may be implemented in a form of an application-specific integrated circuit (ASIC).

According to an embodiment, each component (e.g., a module or a program) of components described in the disclosure may include a single entity or multiple entities. Some of the plurality of entities may be separately disposed in different components. According to an embodiment, one or more of the components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

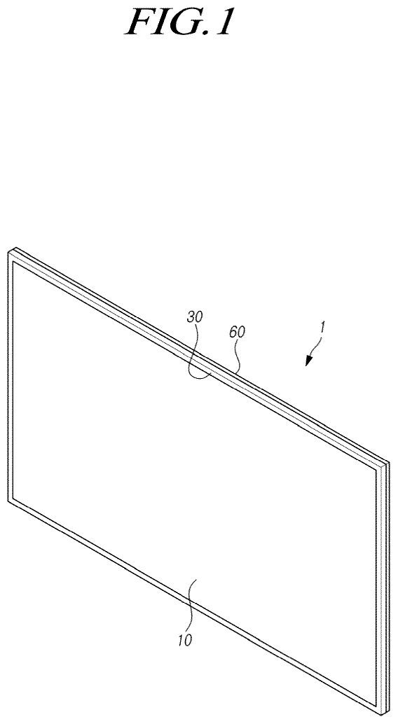

FIG. 1 is a perspective view illustrating a display device according to an embodiment of the disclosure.

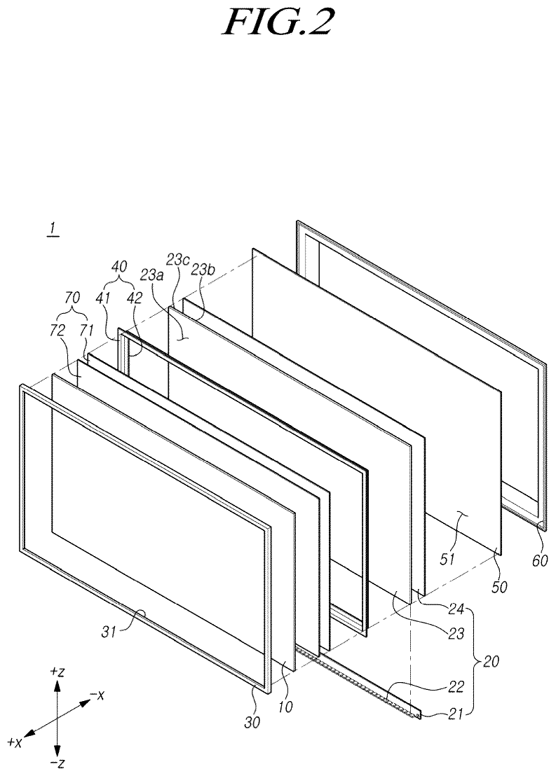

FIG. 2 is an exploded perspective view illustrating a display device according to an embodiment of the disclosure.

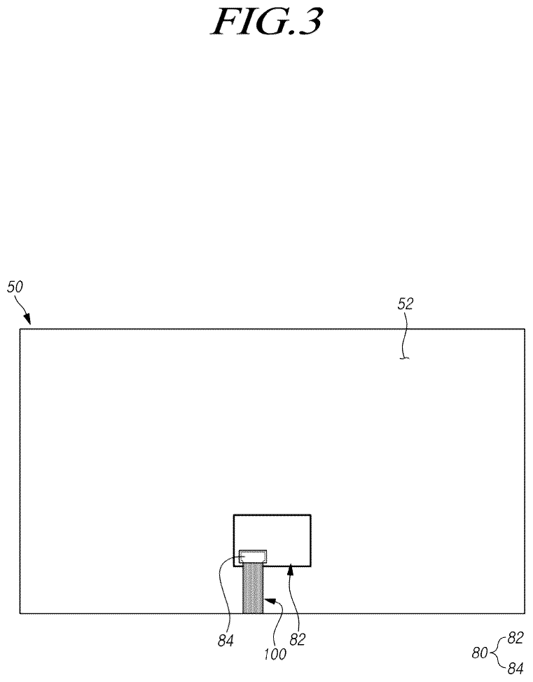

FIG. 3 is a rear view illustrating a display rear chassis according to an embodiment of the disclosure.

According to an embodiment, the display device 1 is a device capable of processing an image signal received from the outside and visually displaying the processed image. Hereinafter, a case where the display device 1 is a television (TV) is illustrated, but embodiments of the disclosure are not limited thereto. For example, the display device 1 may be implemented in various forms such as a monitor, portable multimedia device, portable communication device, and portable computing device, and the display device 1 is not limited in form. For example, the display device 1 may include any type of device that displays images visually.

According to an embodiment, as illustrated in FIG. 1, the display device 1 may be a flat display device in which the display panel 10 displaying an image is flat. According to some embodiments, the display device may be a curved display device with a curved display panel, or a bendable display device where the display panel may be deformed from a flat surface to a curved surface or from a curved surface to a flat surface, or the curvature of the curved surface may change.

Referring to FIGS. 1 to 3, a display device 1 according to an embodiment may include a display panel 10, a backlight unit 20, a chassis assembly (e.g., a front chassis 30, a middle mold 40, and a rear chassis 50), a rear cover 60, an optical sheet 70, and at least one circuit board assembly 80 and a cable 100.

According to an embodiment, the display panel 10 may be configured to display visual information such as an image and/or a video. The display panel 10 may include an LCD panel. The LCD panel may display images using liquid crystals representing optical properties according to changes in voltage and temperature. However, embodiments of the disclosure are not limited thereto, and the display panel 10 may include a light emitting diode (LED) panel or an organic light emitting diode (OLED) panel.

According to an embodiment, the backlight unit 20 may be provided to provide light to the display panel 10. The backlight unit 20 may be disposed under the display panel 10 (e.g., in the −Z-axis direction). The backlight unit 20 may radiate light toward the display panel 10.

In the drawings, it was illustrated that the display device 1 is a non-emissive display device including the backlight unit 20, but this is merely an example, and the display device 1 may be an emissive display device. When the display device 1 is an emissive display device, the backlight unit 20 may be omitted.

According to an embodiment, the backlight unit 20 may be an edge-type backlight unit in which a light source 22 is disposed on any one of the four sides of the display panel 10. According to some embodiments, the display device may include a direct-type backlight unit in which a light source is disposed under the display panel.

According to an embodiment, the backlight unit 20 may include a light source printed circuit board 21, a plurality of light sources 22 mounted (or disposed) on the light source printed circuit board 21, and optical members (e.g., a light guide plate 23 and a reflector sheet 24) disposed on an optical path of the light emitted from the plurality of light sources 22.

According to an embodiment, a plurality of light sources 22 may be mounted in a line on a substrate (e.g., the light source printed circuit board 21) of the backlight unit 20. A circuit pattern for transferring driving power and signals to the light source 22 may be printed on the substrate (e.g., the light source printed circuit board 21). In FIG. 2, one substrate (e.g., one light source printed circuit board 21) is illustrated, but embodiments of the disclosure are not limited thereto, and a plurality of substrates (e.g., a plurality of light source printed circuit boards 21) may be provided.

According to an embodiment, the light source 22 may include a light emitting diode (LED). The LED may be provided in the form of a package including an LED chip mounted on a substrate and filled with a resin. Meanwhile, a cold cathode fluorescent lamp (CCFL) or an external electrode fluorescent lamp (EEFL) may be used as the light source 22.

According to an embodiment, the optical members (e.g., the light guide plate 23 and the reflector sheet 24) may be disposed on the propagation path of light emitted from the light source 22. The optical members (e.g., the light guide plate 23 and the reflector sheet 24) may guide the propagation direction of light or enhance light characteristics.

According to an embodiment, the optical members may include a light guide plate 23 that evenly distributes light emitted from the light source 22 toward the display panel 10, and a reflector sheet 24 that reflects light to prevent light loss.

According to an embodiment, the light guide plate 23 may be formed of a polymethyl methacrylate (PMMA) material. The light guide plate 23 may be provided with a pattern for changing the path of light. In the edge-type backlight unit, the light source 22 may be positioned on the side of the light guide plate 23. For example, the light source 22 may be disposed to correspond to at least one side 23c among the four sides of the light guide plate 23. Light incident on the side of the light guide plate 23 may be scattered from a pattern formed on a rear surface 23b of the light guide plate 23 and emitted through a front surface 23a of the light guide plate 23. The light guide plate 23 may be disposed so that the side surface of the light guide plate 23 is spaced apart from the light source 22 by a predetermined distance in consideration of thermal expansion.

According to an embodiment, the reflector sheet 24 may reflect light emitted from the light source 22 so that light is not lost on the rear surface 23b of the light guide plate 23. The reflector sheet 24 may be provided in various forms such as a sheet, a film, and a plate. For example, the reflector sheet 24 may be formed by coating a base material with a highly reflective material. The base material may include at least one from among stainless steel, brass, aluminum, and polyethylene terephthalate (PET). At least one from among silver and Tio2 may be included as the highly reflective coating agent.

According to an embodiment, the optical sheet 70 may enhance optical characteristics of the display device 1. The optical sheet 70 may be disposed in front of the light guide plate 23 (e.g., +X-axis direction) to enhance light characteristics of light emitted from the light guide plate 23. The optical sheet 70 may be disposed between the light guide plate 23 and the display panel 10.

According to an embodiment, the optical sheet 70 may include a diffuser sheet 71 and a prism sheet 72.

According to an embodiment, the diffuser sheet 71 may disperse light to offset or minimize the pattern of the light guide plate 23. In general, the light guided through the light guide plate 23 directly enters the eye, so the pattern of the light guide plate 23 is reflected in the eye as it is.

According to an embodiment, the prism sheet 72 may enhance light luminance by refocusing light that has reduced luminance as it passes through the diffuser sheet 71. For example, the prism sheet 72 may be a dual brightness enhancement film (DBEF) sheet, which is a high-luminance prism sheet.

According to an embodiment, the chassis assembly (e.g., the front chassis 30, the middle mold 40, and the rear chassis 50) may be provided to receive the display panel 10 and/or the backlight unit 20. The chassis assembly (e.g., the front chassis 30, the middle mold 40, and the rear chassis 50) may be provided to support the display panel 10 and/or the backlight unit 20.

According to an embodiment, the chassis assembly may include a front chassis 30, a middle mold 40, and a rear chassis 50.

According to an embodiment, the front chassis 30 may include an opening 31 for exposing the display panel 10.

According to an embodiment, the middle mold 40 may include a middle mold side portion 41 and an intermediate support portion 42 protruding inward from the middle mold side portion 41 to support the display panel 10 and the optical member while maintaining the gap.

According to an embodiment, the rear chassis 50 may support the backlight unit 20. Various components of the display device 1, such as the front chassis 30 and the middle mold 40, may be fixedly supported on the rear chassis 50.

According to an embodiment, the substrate (e.g., the light source printed circuit board 21) of the backlight unit 20 may be mounted on a front surface 51 of the rear chassis 50. For example, the rear chassis 50 may serve to dissipate heat generated from the light source 22 to the outside. Heat generated from the light source 22 may be transferred to the rear chassis 50 via the substrate (e.g., the light source printed circuit board 21), and may be radiated from the rear chassis 50. For example, the rear chassis 50 may be formed of various metal materials such as aluminum and stainless steel having good thermal conductivity, or plastic materials such as acrylonitrile butadiene styrene (ABS) resin. Further, the substrate (e.g., the light source printed circuit board 21) may also be a metal printed circuit board (PCB) formed of aluminum having good thermal conductivity.

According to an embodiment, at least one from among the front chassis 30, the middle mold 40, and the rear chassis 50 may be omitted or integrally formed with each other.

According to an embodiment, the rear cover 60 may be disposed to surround the chassis assembly (e.g., the front chassis 30, the middle mold 40, and the rear chassis 50) to protect and receive the chassis assembly (e.g., the front chassis 30, the middle mold 40, and the rear chassis 50). For example, the rear cover 60 may be coupled at the rear (e.g., −X axis direction) of the rear chassis 50 of the chassis assembly (e.g., the front chassis 30, the middle mold 40, and the rear chassis 50).

According to an embodiment, at least one circuit board assembly 80 (e.g., at least one printed board assembly) may be received in the chassis assembly (e.g., the front chassis 30, the middle mold 40, and the rear chassis 50). The circuit board assembly 80 may be disposed on a rear surface 52 of the rear chassis 50. For example, the circuit board assembly 80 may include an integrated circuit (IC) for wirelessly transmitting and receiving data, signals, or power. In FIG. 3, one circuit board assembly 80 is illustrated, but embodiments of the disclosure are not limited thereto, and a plurality of circuit board assemblies 80 may be provided.

According to an embodiment, the circuit board assembly 80 may include a circuit board 82 and a connector 84 mounted on the circuit board 82.

According to an embodiment, the circuit board 82 may be a PCB. The circuit board 82 may be provided to drive and control at least one from among the display panel 10 and the backlight unit 20. The circuit board 82 may supply power for driving the display device 1 or control the operation of the display device 1. For example, the circuit board 82 may include at least one from among a main board, a switched mode power supply (SMPS), and a source board. Various electronic components may be mounted on the circuit board 82 according to their intended purpose.

According to an embodiment, the circuit board 82 may be provided by forming a line with a copper foil on a thin substrate formed of an insulator such as an epoxy resin or bakelite resin as a base, and then printing a lead resist. Meanwhile, according to some embodiments, the circuit board 82 may include a plurality of circuit patterns. The circuit board 82 may be configured as either a single-layer or a multi-layer structure.

According to an embodiment, the connector 84 may be provided to electrically connect the cable 100 and the circuit board assembly 80.

According to an embodiment, the cable 100 may be electrically connected to an electronic component inside the display device 1. For example, the cable 100 may electrically connect the display panel 10 and the circuit board 82. For example, the cable 100 may electrically connect the backlight unit 20 to the circuit board 82. One end portion of the cable 100 may be electrically connected to the connector 84 provided on the circuit board 82, and the other end portion of the cable 100 may be electrically connected to the display panel 10 or the backlight unit 20. The cable 100 may allow various signals to be transmitted between the display panel 10 or the backlight unit 20 and the circuit board 82. Further, the cable 100 may electrically connect a plurality of circuit board assemblies 80 to each other.

According to an embodiment, the cable 100 may be electrically connected to an electronic component (e.g., the circuit board assembly 80) inside the display device 1 while at least a portion of a fixing portion 120 (e.g., a fixing portion body 122) to be described below is separated (or cut) from the cable body 110 when the display device 1 is manufactured.

According to an embodiment, the cable 100 may have a structure that may be bent or folded at least once. For example, the cable 100 may include at least one from among a flexible flat cable (FFC) and a flexible printed circuit board (FPCB). Hereinafter, a case where the cable 100 is an FFC is illustrated as an example in the drawings.

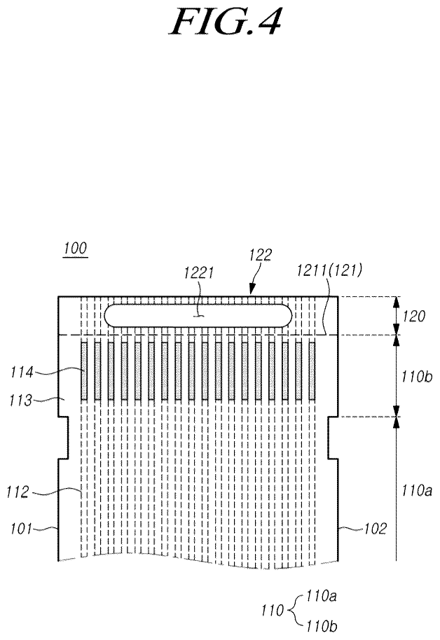

FIG. 4 is a plan view illustrating an end portion of a cable according to an embodiment of the disclosure.

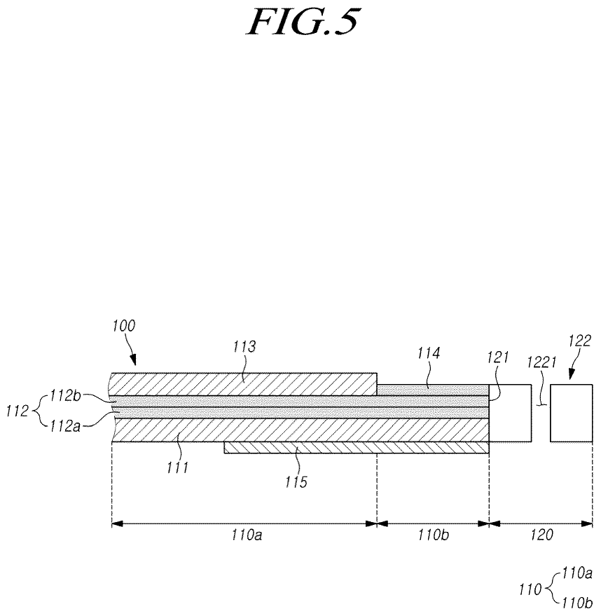

FIG. 5 is a vertical cross-sectional view illustrating a cable according to an embodiment of the disclosure.

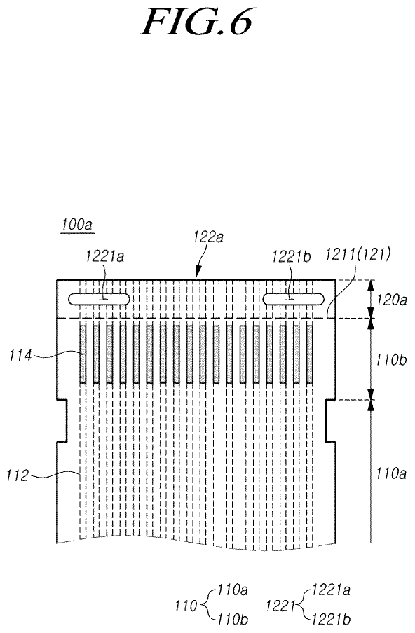

FIG. 6 is a plan view illustrating an end portion of a cable according to an embodiment of the disclosure.

The embodiments of FIGS. 4 to 6 may be selectively combined with the embodiments of FIGS. 1 to 3 and 7 to 13.

The configuration of the cable 100a of FIG. 6 may be identical in whole or part to the configuration of the cable 100 of FIGS. 1 to 4.

Referring to FIGS. 4 to 6, the cable 100 according to an embodiment may include a cable body 110 and a fixing portion 120 connected to the cable body 110 to be at least partially separable (or removable or cuttable).

According to an embodiment, the cable body 110 of the cable 100 may include a base layer 111, at least one conductive line 112, a cover layer 113, a protective layer 114, and a reinforcement layer 115.

According to an embodiment, the base layer 111 may be formed to extend to have a length and a width set in a manufacturing process. The base layer 111 may be formed of a thermally adhesive synthetic resin having insulation (e.g., electrical insulation), heat resistance, flexibility, and resilience while having mechanical strength such as tensile strength. For example, the base layer 111 may be selected from synthetic resins including nylon, acetate, and polyester-based resins. Further, the base layer 111 may be formed of various materials capable of securing the flexibility of the flexible flat cable. The base layer 111 may be referred to as a first insulation layer.

According to an embodiment, the conductive line (or conductor) 112 may be disposed on the base layer 111. When the extending direction (or the length direction) of the base layer 111 is defined as a first direction, the conductive lines 112 may be disposed in a direction parallel to the extending direction (e.g., the first direction) of the base layer 111. When the width direction perpendicular to the length direction of the base layer 111 is defined as a second direction, a plurality of conductive lines 112 may be disposed with respect to each other in the width direction (e.g., the second direction) of the base layer 111. The conductive lines 112 may be disposed adjacent to each other in the width direction. The conductive lines 112 may be spaced apart from each other at regular intervals and disposed parallel to each other so as not to contact each other. The conductive line 112 may be formed of a conductive material to transmit an electrical signal or current. For example, the conductive line 112 may be formed of a conductive material such as silver, copper, nickel, cobalt, or a combination thereof. The cable 100 may be formed by disposing the conductive line 112 manufactured through a separate manufacturing process on one surface (e.g., the upper surface) of the base layer 111, covering the cover layer 113 thereon, and then pressing it.

According to an embodiment, the conductive line 112 may be formed by printing a conductive paste in a stripe shape on one surface of the base layer 111. For example, the conductive paste may be a composition including 50 to 70 wt% silver (Ag) filler mixed with 30 to 50 wt% binder. In addition to the silver filler, as the conductive paste, various conductive materials may be used, such as a copper (Cu) filler, a filler where silver is coated on copper, nickel, cobalt, or a combination thereof in various composition ratios. Various methods, including gravure printing, inkjet printing, offset printing, silk screen printing, rotary screen printing, or similar techniques, may be employed to perform printing techniques for forming the conductive lines 112.

According to an embodiment, the conductive line 112 may include a conductive layer 112a and a coating layer 112b. The coating layer 112b may be provided to reinforce corrosion resistance of the conductive layer 112a. For example, the conductive layer 112a may be a copper foil, and the coating layer 112b may be nickel plating.

According to an embodiment, the cover layer 113 may be disposed on the base layer 111 on which the conductive line 112 is disposed. The cover layer 113 may cover at least a portion of the conductive line 112. For example, the cover layer 113 covers all of the conductive line 112 except for a part of the conductive line 112 that is covered by the connection terminal (e.g., the protective layer 114), thereby preventing the conductive line 112 from being exposed to the outside. The cover layer 113 may cover at least a portion of the conductive line 112 disposed on one surface of the base layer 111 and then may be bonded to the base layer 111 through a lamination process.

According to an embodiment, the cover layer 113 may extend to have a length and a width set in a manufacturing process, similar to the base layer 111. The cover layer 113 may coat the conductive line 112 disposed on the base layer 111 and may be formed to be narrower than the width of the base layer 111. The cover layer 113 may be formed of a thermally adhesive synthetic resin having insulation (e.g., electrical insulation), heat resistance, flexibility, and resilience while having mechanical strength such as tensile strength. For example, the cover layer 113 may be selected from synthetic resins including nylon, acetate, and polyester resins. Further, the cover layer 113 may be formed of various materials capable of securing the flexibility of the flexible flat cable. The cover layer 113 may be referred to as a second insulation layer.

According to an embodiment, the protective layer 114 may be disposed on an area of the conductive line 112 where the cover layer 113 is not provided. For example, the protective layer 114 may be provided to prevent corrosion of a portion of the conductive line 112 exposed to the outside. For example, the protective layer 114 may be a coating layer where a material such as gold is plated on a portion of the conductive line 112 exposed to the outside. The protective layer 114 may be referred to as a connection terminal.

According to an embodiment, the reinforcement layer 115 may be disposed on the other side surface (e.g., the lower surface) opposite to one side (e.g., the upper surface) of the base layer 111. The reinforcement layer 115 may be provided to reinforce the mechanical strength of the cable 100 during bending or twisting of the cable 100. For example, the reinforcement layer 115 may be disposed to extend across the cable body 110 and/or the fixing portion 120 of the cable 100. In this case, the reinforcement layer 115 may prevent damage to a fastening portion 110b of the cable body 110 when the electronic component of the cable 100 is fastened to the connector.

According to an embodiment, the cable body 110 may include a body portion 110a and fastening portions 110b provided at two opposite ends of the body portion 110a.

According to an embodiment, the body portion 110a may be a portion of the cable body 110 of the cable 100 where the conductive line 112 is not exposed to the outside.

According to an embodiment, the fastening portion 110b may be a portion of the cable body 110 including the connection terminal (e.g., the protective layer 114) formed on the conductive line 112 exposed by exposing at least a portion of the conductive line 112 to the outside. The fastening portion 110b may be a portion of the cable body 110 that may be inserted into the connector (e.g., the connector 84 of FIG. 3) of the circuit board assembly (e.g., the circuit board assembly 80 of FIG. 3). The cable 100 may be electrically connected to a circuit board (e.g., the circuit board 82 of FIG. 3) of the circuit board assembly 80 through the connection terminal (e.g., the protective layer 114) of the fastening portion 110b.

According to an embodiment, the fixing portion 120 may extend from the fastening portion 110b of the cable body 110. The width of the fixing portion 120 may be substantially the same as the width of the fastening portion 110b of the cable body 110.

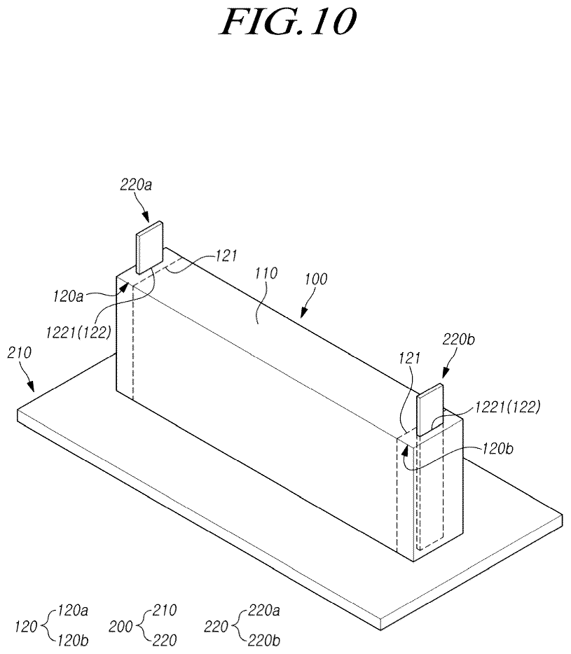

According to one embodiment, the fixing portion 120 may be provided as a pair. The pair of fixing portions 120 may include a first fixing portion (e.g., the first fixing portion 120a of FIG. 10) connected to one end (e.g., a first end) of the cable body (110) and a second fixing portion (e.g., a second fixing member 120b of FIG. 10) connected to the other end (e.g., a second end) opposite to the one end of the cable body 110.

According to an embodiment, the fixing portion 120 may include a cutting portion 121 and a fixing portion body 122.

According to an embodiment, the cutting portion 121 may include a perforation line 1211 extending by a predetermined distance along the connection portion between the fixing portion (e.g., the fixing portion body 122) and the cable body 110. The perforation line 1211 may include a plurality of holes (or recesses) formed in at least one row and spaced apart from each other. For example, the perforation line 1211 may have a dot-line shape. For example, the perforation line 1211 may be formed through a punching, slitting, or laser cutting process.

According to an embodiment, the perforation line 1211 may be provided at a boundary between the fastening portion 110b of the cable body 110 and the fixing portion body 122. The perforation line 1211 may be disposed to be adjacent to the connection terminal (e.g., the protective layer 114) on the fastening portion 110b of the cable body 110. The perforation line 1211 may be positioned between the connection terminal (e.g., the protective layer 114) of the fastening portion 110b and a fixing recess 1221. The perforation line 1211 may extend from a left end 101 to a right end 102 of the cable 100 along the width direction (e.g., the second direction) of the cable 100.

According to an embodiment, the fixing portion body 122 may be separably (or cuttably) connected to the cable body 110. For example, the fixing portion body 122 may be separated from the cable body 110 by cutting. When an external force (e.g., torsional force or cutting force) acts on the fixing portion 120, the fixing portion body 122 may be separated from the cable body 110 by the external force. For example, when an external force is applied to the fixing portion 120, the fixing portion body 122 may be separated from the cable body 110 along the perforation line 1211 of the cutting portion 121.

According to an embodiment, the fixing portion body 122 may include a fixing recess 1221. A fixing protrusion (e.g., a fixing protrusion 220 of FIG. 10) of a cable tray (e.g., a cable tray 200 of FIG. 10) to be described below may be inserted into the fixing recess 1221. The cable 100 may be stably received in the cable tray 200 through the fixing recess 1221. For example, the fixing recess 1221 may have a rectangular shape, but embodiments of the disclosure are not limited thereto.

According to an embodiment, as illustrated in FIG. 6, a plurality of fixing recesses 1221a and 1221b may be provided. A pair of fixing recesses 1221a and 1221b may be provided in the fixing portion body 122a of each fixing portion 120a to be spaced apart from each other. In this case, the cable 100a may be more stably received in the cable tray as the fixing protrusions of the cable tray are inserted into the fixing recesses 1221a and 1221b, respectively.

According to an embodiment, the structures of the fixing portions 120 and 120a may be substantially the same as the cable body 110 of the cables 100 and 100a except for the perforation line 1211 and the fixing recess 1221. For example, the fixing portion 120 or 120a may be a portion of the cable body 110 that extends in the length direction (e.g., the first direction) from the cable body 110 of the cable 100 or 100a and may be separated (or removed or cut) from the cable body 110 through the cutting portion 121. In this case, the fixing portion 120 or 120a may include at least one from among a base layer 111, at least one conductive line 112, a cover layer 113, a protective layer 114, and a reinforcement layer 115, like the cable body 110 of the cable 100. For example, the fixing portion 120 or 120a may be integrally formed from at least one from among the base layer 111, at least one conductive line 112, the cover layer 113, the protective layer 114, and the reinforcement layer 115 of the cable body 110.

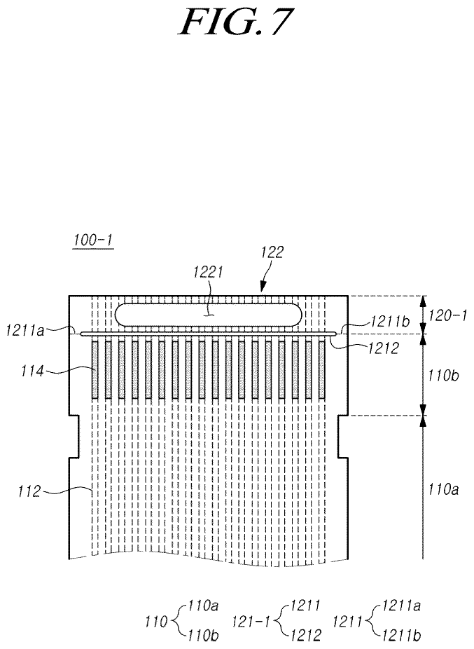

FIG. 7 is a plan view illustrating an end portion of a cable according to an embodiment of the disclosure.

The embodiment of FIG. 7 may be selectively combined with the embodiments of FIGS. 1 to 6 and FIGS. 8 to 13.

The configuration of the cable 100-1 of FIG. 7 may be identical in whole or part to the configuration of the cable 100 of FIGS. 1 to 5.

Referring to FIG. 7, a cable 100-1 according to an embodiment may include a cable body 110 and a fixing portion 120-1 connected to the cable body 110 to be at least partially separable (or removable or cuttable). According to an embodiment, the cable body 110 may include a body portion 110a and fastening portions 110b provided at two opposite ends of the body portion 110a.

According to an embodiment, the fixing portion 120-1 may include a cutting portion 121-1 and a fixing portion body 122.

According to an embodiment, the cutting portion 121-1 may include at least one perforation line 1211 extending by a predetermined distance along a connection portion between the fixing portion (e.g., the fixing portion body 122) and the cable body 110. The at least one perforation line 1211 may include a first perforation line 1211a and a second perforation line 1211b. The first perforation line 1211a and the second perforation line 1211b may be disposed side by side with a cutting recess 1212 (described below) disposed therebetween. For example, the first perforation line 1211a may be disposed adjacent to the left end 101 of the cable 100-1. For example, the second perforation line 1211b may be disposed adjacent to the right end 102 of the cable 100-1.

According to an embodiment, the cutting portion 121-1 may include a cutting recess 1212 disposed between the first perforation line 1211a and the second perforation line 1211b. The cutting recess 1212 may be provided at a boundary between the fixing portion 120-1 and the fastening portion 110b. The cutting recess 1212 may extend in the width direction (e.g., the second direction) of the cable 100-1. The width of the fixing portion 120-1 may be substantially the same as the sum of the width of the at least one perforation line 1211 and the width of the cutting recess 1212. The width of the cutting recess 1212 may be designed in consideration of an external force (e.g., torsional force or cutting force) required when the fixing portion body 122 is cut through the at least one perforation line 1211. As illustrated in FIG. 7, the width of the cutting recess 1212 may be provided to be longer than the width of the at least one perforation line 1211. For example, by increasing the proportion of the cutting recess 1212 in the width of the fixing portion 120-1, the external force required when the fixing portion body 122 is cut through the perforation line 1211 may be decreased. In this case, the external force required for cutting the fixing portion body 122 is decreased, and thus the fixing portion body 122 may be separated (or removed or cut) from the cable body 110 of the cable 100-1.

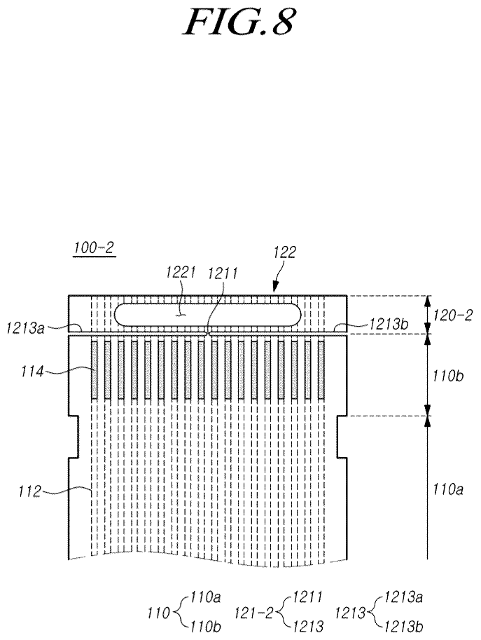

FIG. 8 is a plan view illustrating an end portion of a cable according to an embodiment of the disclosure.

The embodiment of FIG. 8 may be selectively combined with the embodiments of FIGS. 1 to 7 and FIGS. 9 to 13.

The configuration of the cable 100-2 of FIG. 8 may be identical in whole or part to the configuration of the cable 100 of FIGS. 1 to 5.

Referring to FIG. 8, a cable 100-2 according to an embodiment may include a cable body 110 and a fixing portion 120-2 connected to the cable body 110 to be at least partially separable (or removable or cuttable). According to an embodiment, the cable body 110 may include a body portion 110a and fastening portions 110b provided at two opposite ends of the body portion 110a.

According to an embodiment, the fixing portion 120-2 may include a cutting portion 121-2 and a fixing portion body 122.

According to an embodiment, the cutting portion 121-2 may include a perforation line 1211 extending by a predetermined distance along a connection portion between the fixing portion (e.g., the fixing portion body 122) and the cable body 110.

According to an embodiment, the perforation line 1211 may be disposed between a first cutting recess 1213a and a second cutting recess 1213b to be described below. For example, the perforation line 1211 may be positioned at the center of the width of the fixing portion 120-2.

According to an embodiment, the cutting portion 121-2 may include at least one cutting recess 1213 provided at a boundary between the fixing portion body 122 and the fastening portion 110b. The at least one cutting recess 1213 may include a first cutting recess 1213a and a second cutting recess 1213b. The first cutting recess 1213a and the second cutting recess 1213b may be disposed side by side with the perforation line 1211 interposed therebetween. For example, the first cutting recess 1213a may be disposed adjacent to the left end 101 of the cable 100-2. For example, the second cutting recess 1213b may be disposed adjacent to the right end 102 of the cable 100-2.

According to an embodiment, the first cutting recess 1213a may be a space where one side (e.g., left side) of the fixing portion 120-2 is opened by being cut in the width direction of the fixing portion 120-2. For example, one end of the first cutting recess 1213a may be an open end, and the other end of the first cutting recess 1213a may be a fixed end in contact with the perforation line 1211.

According to an embodiment, the second cutting recess 1213b may be a space where the other side (e.g., right side) opposite to the one side of the fixing portion 120-2 is opened by being cut in the width direction of the fixing portion 120-2. For example, one end of the second cutting recess 1213b may be an open end, and the other end of the second cutting recess 1213b may be a fixed end in contact with the perforation line 1211.

According to an embodiment, the at least one cutting recess 1213 may extend in the width direction (e.g., the second direction) of the cable 100-2. The width of the fixing portion 120-2 may be substantially the same as the sum of the width of the perforation line 1211 and the width of the at least one cutting recess 1213.

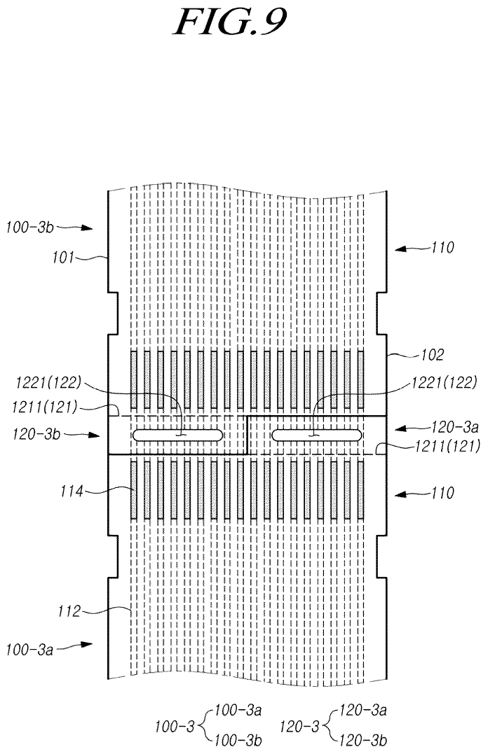

FIG. 9 is a plan view illustrating a plurality of cables connected, according to an embodiment of the disclosure.

The embodiment of FIG. 9 may be selectively combined with the embodiments of FIGS. 1 to 8 and FIGS. 10 to 13.

The configuration of the cable 100-3 of FIG. 9 may be identical in whole or part to the configuration of the cable 100 of FIGS. 1 to 5.

According to an embodiment, the cable 100-3 may be provided in the form of a single band (or tape or film) in which a plurality of cables 100-3a and 100-3b are connected to each other from a manufacturer (or producer) before being electrically connected to an electronic component (e.g., the display panel 10 or circuit board assembly 80 of FIG. 1). The cables 100-3 in the form of a single band in which the plurality of cables 100-3a and 100-3b are connected to each other may be referred to as a cable reel or a cable roll.

Referring to FIG. 9, each of plurality of cables 100-3a and 100-3b of the cable 100-3 according to an embodiment may include a cable body 110 and a fixing portion 120-3 connected to the cable body 110 to be at least partially separable (or removable or cuttable). According to an embodiment, the cable body 110 may include a body portion 110a and fastening portions 110b provided at two opposite ends of the body portion 110a.

According to an embodiment, the fixing portion 120-3 may include a cutting portion 121 and a fixing portion body 122.

According to an embodiment, the fixing portion 120-3 may include a first fixing portion 120-3a connected to one end portion of the cable body 110 to be at least partially cuttable, and a second fixing portion 120-3b connected to the other end portion of the cable body 110 to be at least partially cuttable. The cutting portion 121 of each of the first fixing portion 120-3a and the second fixing portion 120-3b may include a perforation line 1211. The fixing portion body 122 of each of the first fixing portion 120-3a and the second fixing portion 120-3b may include a fixing recess 1221.

According to an embodiment, the first fixing portion 120-3a and the second fixing portion 120-3b may be provided at positions opposite to each other in the width direction (e.g., the second direction) of the cable 100-3 with respect to the cable body 110. For example, as illustrated in FIG. 9, the first fixing portion 120-3a may be connected to one end portion of the cable body 110, shifted toward the right end 102 of the cable 100-3. For example, as illustrated in FIG. 9, the second fixing portion 120-3b may be connected to the other end portion of the cable body 110, shifted toward the left end 101 of the cable 100-3.

According to an embodiment, the sum of the width of the first fixing portion 120-3a and the width of the second fixing portion 120-3b may be substantially the same as the width of the cable 100-3. The length of the first fixing portion 120-3a may be substantially the same as the length of the second fixing portion 120-3b. The respective fixing portions (e.g., the first fixing portions 120-3a and the second fixing portions 120-3b) of the plurality of cables 100-3a and 100-3b connected to each other may be engaged with each other. For example, the respective fixing portions (e.g., the first fixing portions 120-3a and the second fixing portions 120-3b) of the plurality of cables 100-3a and 100-3b connected to each other may have various engagement structures such as irregular structures and diagonal structures. For example, the first fixing portion 120-3a of one cable 100-3a and the second fixing portion 120-3b of the other cable 100-3b, connected to the cable 100-3a, may be engaged to each other, forming a single band-type cable 100-3 before being separated.

In the case of the fixing portion 120-3 of the cable 100-3 according to the embodiment of FIG. 9, the width of the fixing portion 120-3 may be narrower than the fixing portions 120, 120a, 120-1, and 120-2 of the cables 100, 100a, 100-1, and 100-2 according to the embodiments of FIGS. 4 to 8. In this case, the manufacturing cost of the cable 100-3 may be decreased by substantially reducing the amount (or volume) of the fixing portion 120-3 discarded when the fixing portion 120-3 is cut.

FIG. 10 is a perspective view illustrating a plurality of cables loaded on a cable tray according to an embodiment of the disclosure.

The embodiment of FIG. 10 may be selectively combined with the embodiments of FIGS. 1 to 9, and FIGS. 11 to 13.

According to an embodiment, the plurality of cables 100 may be loaded on the cable tray 200 and stored or transported. The plurality of cables 100 loaded on the cable tray 200 may be used in an automated manufacturing process of a display device (e.g., the display device 1 of FIGS. 1 and 2) through a pickup device (e.g., a robot).

Referring to FIG. 10, the cable tray 200 according to an embodiment may include a tray body 210 and at least one fixing protrusion 220.

According to an embodiment, the tray body 210 may have a flat plate shape, but embodiments of the disclosure are not limited thereto. For example, the tray body 210 may have a bowl shape.

According to an embodiment, the at least one fixing protrusion 220 may protrude from one surface (e.g., the upper surface) of the tray body 210. For example, the at least one fixing protrusion 220 may vertically protrude and extend from one surface of the tray body 210. The at least one fixing protrusion 220 may be provided at a position corresponding to the at least one fixing recess 1221 of the fixing portion 120 of the cable 100.

According to an embodiment, a pair of fixing protrusions 220 may be provided. The pair of fixing protrusions 220 may include a first fixing protrusion 220a and a fixing protrusion 220b. The pair of fixing protrusions 220a and 220b may be disposed to be spaced apart from each other. The pair of fixing protrusions 220a and 220b may be disposed to face each other.

According to an embodiment, the cable 100 may be fixed on the cable tray 200 based on the fixing protrusions 220a and 220b of the cable tray 200 being inserted into the fixing recesses 1221 of the fixing portion 120. For example, the plurality of cables 100 may be loaded vertically on the cable tray 200 through the fixing protrusions 220 of the cable tray 200. In this case, the plurality of cables 100 may be securely fixed and/or loaded by the fixing protrusions 220 of the cable tray 200, thereby preventing any twisting or tangling of the cables 100 that may arise during the transport of the cable tray loaded with these cables.

According to an embodiment, each of the plurality of cables 100 loaded on the cable tray 200 may be cut (or separated) through the cutting portion 121 in a state in which each fixing portion body 122 is fixed by the fixing protrusion 220 of the cable tray 200 while being picked up by a pickup device (e.g., robot), and an automated process for the display device (e.g., the display device 1 of FIGS. 1 and 2) may be achieved by the pickup device.

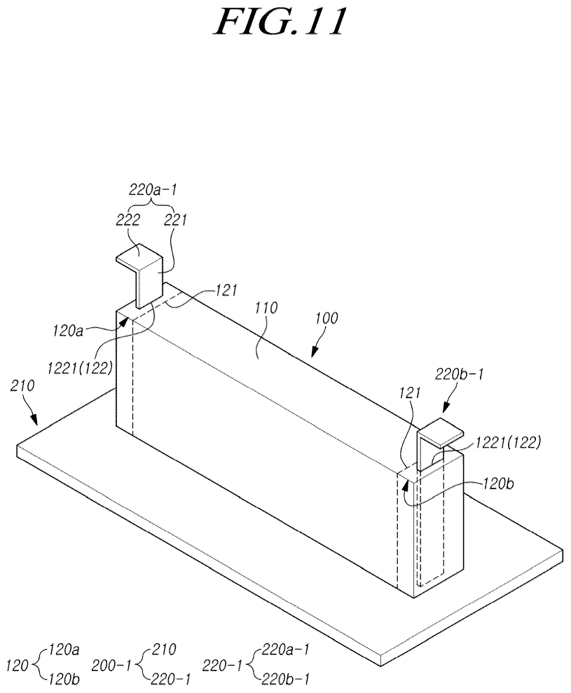

FIG. 11 is a perspective view illustrating a plurality of cables loaded on a cable tray according to an embodiment of the disclosure.

The embodiment of FIG. 11 may be selectively combined with the embodiments of FIGS. 1 to 10, 12, and 13.

The configuration of the cable tray 200-1 of FIG. 11 may be identical in whole or part to the configuration of the cable tray 200 of FIG. 10.

Referring to FIG. 11, a cable tray 200-1 according to an embodiment may include a tray body 210 and at least one fixing protrusion 220-1.

According to an embodiment, a pair of fixing protrusions 220-1 may be provided. The pair of fixing protrusions 220a-1 and 220b-1 may be disposed to be spaced apart from each other. The pair of fixing protrusions 220a-1 and 220b-1 may be disposed to face each other.

According to an embodiment, each of the fixing protrusions 220a-1 and 220b-1 may include an extension 221 vertically extending from one surface of the tray body 210 and a stopper 222 bent from the extension 221. For example, the stopper 222 may extend in a direction (e.g., a horizontal direction) from the extension 221 that is different from an extending direction (e.g., a vertical direction) of the extension 221.

According to an embodiment, the stopper 222 may be bent outward from the extension 221. For example, the respective stoppers 222 of the fixing protrusions 220a-1 and 220b-1 may be bent in opposite directions (e.g., opposite horizontal directions) with respect to each other. However, embodiments of the disclosure are not limited thereto. The stoppers 222 may be formed in a state in which the plurality of cables 100 are fixed (or inserted) to the extensions 221 of the fixing protrusions 220-1.

According to an embodiment, the stopper 222 may be provided to limit the vertical movement of the fixing portion 120 of the cable 100 while each of the plurality of cables 100 loaded on the cable tray 200-1 is picked up by a pickup device (e.g., robot). In this case, each fixing portion body 122 may be more easily cut (or separated) by the fixing protrusion 220-1 of the cable tray 200-1.

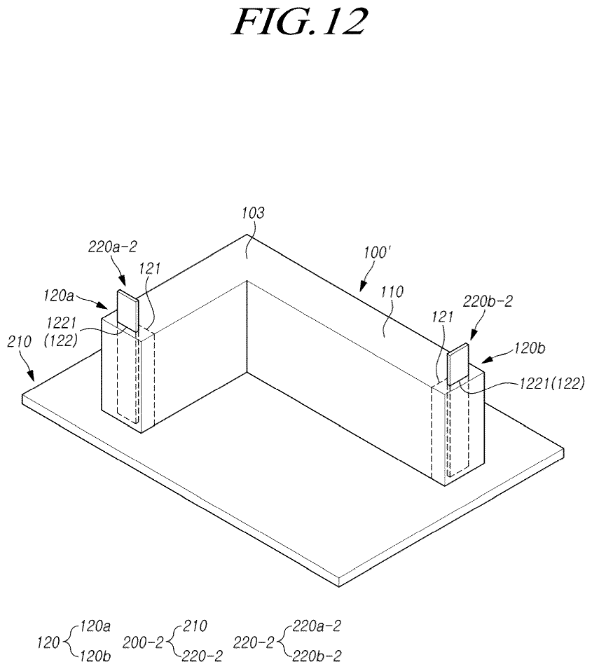

FIG. 12 is a perspective view illustrating a plurality of cables loaded on a cable tray according to an embodiment of the disclosure.

The embodiment of FIG. 12 may be selectively combined with the embodiments of FIGS. 1 to 11 and 13.

The configuration of the cable tray 200-2 of FIG. 12 may be identical in whole or part to the configuration of the cable tray 200 of FIG. 10.

According to an embodiment, the cable 100′ may be an FFC or an FPCB that may be bent or folded as described above. The cable 100′ may be bent or folded at least once to avoid interference with the counterpart according to the arrangement between components in the display device (e.g., the display device 1 of FIGS. 1 and 2). For example, as illustrated in FIG. 12, the cable 100′ may be bent or folded around a vertical axis to form a bending portion 103 between two opposite ends of the cable 100′ where the fixing portions 120 are provided.

Referring to FIG. 12, a cable tray 200-2 according to an embodiment may include a tray body 210 and at least one fixing protrusion 220-2.

According to an embodiment, a pair of fixing protrusions 220-2 may be provided. The pair of fixing protrusions 220a-2 and 220b-2 may be disposed to be spaced apart from each other. The pair of fixing protrusions 220a-2 and 220b-2 may be disposed to be offset from each other. For example, the fixing protrusions 220a-2 and 220b-2 may have different rotational orientations from each other due to the bending portion 103, and the fixing protrusions 220a-2 and 220b-2 may be spaced apart from the bending portion 103 in respective directions that cross each other.

According to an embodiment, the cable 100′ may be fixed on the cable tray 200-2 based on the fixing protrusions 220a-2 and 220b-2 of the cable tray 200-2 being inserted into the fixing recesses 1221 of the fixing portions 120. As such, even if the cable 100′ is bent or folded, the opposing end portions of the cable 100′ may be secured by the fixing protrusions 220a-2 and 220b-2 of the cable tray 200-2. This prevents any tilting phenomenon that could arise due to the thickness of the bending portion 103 during the loading of a plurality of cables 100′.

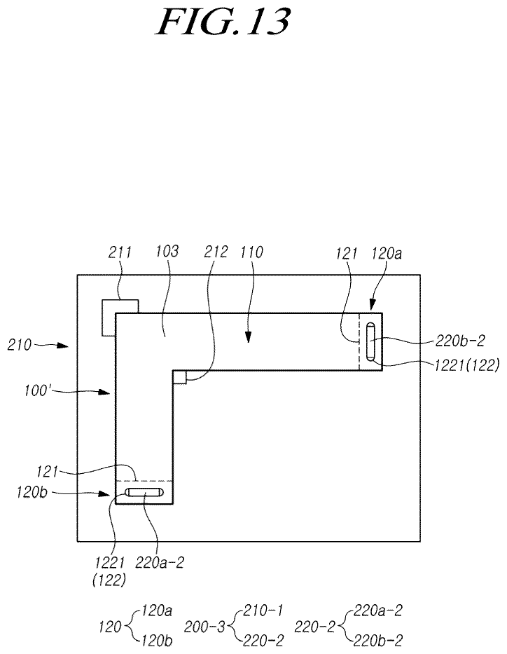

FIG. 13 is a plan view illustrating a plurality of cables loaded on a cable tray according to an embodiment of the disclosure.

The embodiment of FIG. 13 may be selectively combined with the embodiments of FIGS. 1 to 12.

The configuration of the cable tray 200-3 of FIG. 13 may be identical in whole or part to the configuration of the cable tray 200-2 of FIG. 12.

Referring to FIG. 13, a cable tray 200-3 according to an embodiment may include a tray body 210, at least one fixing protrusion 220-2, and guide ribs (e.g., a first guide rib 211 and a second guide rib 212).

According to an embodiment, a pair of fixing protrusions 220-2 may be provided. The pair of fixing protrusions 220a-2 and 220b-2 may be disposed to be spaced apart from each other. The pair of fixing protrusions 220a-2 and 220b-2 may be disposed to be offset from each other.

According to an embodiment, the guide ribs (e.g., the first guide rib 211 and the second guide rib 212) may be disposed to at least partially surround the bending portion 103 of the cable 100′. The guide ribs (e.g., the first guide rib 211 and the second guide rib 212) may protrude and extend from one surface of the tray body 210. The guide ribs may include a first guide rib 211 provided to surround one side (e.g., outside) of the bending portion 103 of the cable 100′ and a second guide rib 212 provided to surround the other side (e.g., inside) of the bending portion 103 of the cable 100′. The bending portion 103 of the cable 100′ may be disposed between the first guide rib 211 and the second guide rib 212.

According to an embodiment, the cable 100′ may be fixed on the cable tray 200-2 based on the fixing protrusions 220a-2 and 220b-2 of the cable tray 200-3 being inserted into the fixing recesses 1221 of the fixing portions 120. In this case, the bending portion 103 of the cable 100′ may be surrounded between the first guide rib 211 and the second guide rib 212. In this case, two opposite ends of the cable 100′ may be fixed by the fixing protrusions 220a-2 and 220b-2 of the cable tray 200-2, and the guide ribs (e.g., the first guide rib 211 and the second guide rib 212) may surround and fix the bending portion 103 of the cable 100′, more effectively preventing the tilt due to the thickness of the bending portion 103.

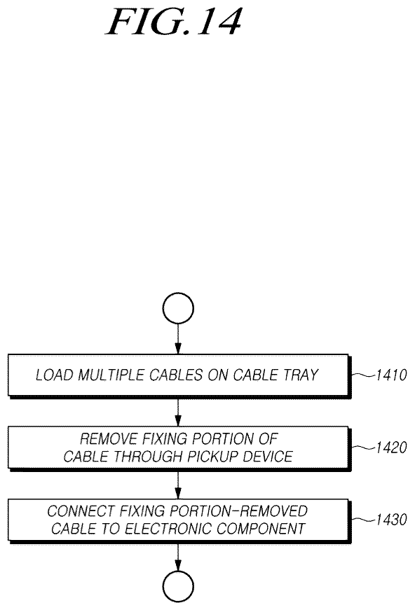

FIG. 14 is a flowchart illustrating a method for manufacturing a display device according to an embodiment of the disclosure.

The embodiment of FIG. 14 may be selectively combined with the embodiments of FIGS. 1 to 13.

Hereinafter, an automated manufacturing process of a display device (e.g., the display device 1 of FIGS. 1 and 2) using a pickup device (e.g., a robot) is described with reference to FIG. 14.

Referring to FIG. 14, a plurality of cables 100 according to an embodiment may be loaded on the cable tray 200 by having the fixing protrusions 220 of the cable tray 200 inserted through the fixing recesses 1221 of the fixing portions 120 of the cable 100 (operation 1410).

According to an embodiment, the pickup device may separate or remove the fixing portion body 122 connected to the cable body 110 through the cutting portion 121 by picking up each cable 100 loaded on the cable tray 200 and then performing a separation (or cutting) operation (e.g., vertical, horizontal, or twisting operation) on the fixing portion 120 of the cable 100 (operation 1420).

According to an embodiment, the cable 100 from which the fixing portion body 122 is separated or removed may be electrically connected to the electronic component (operation 1430) by the fastening portion 110b being fastened to the electronic component (e.g., the display panel 10 of FIG. 1 or the circuit board assembly 80 of FIG. 3) provided in the display device.

A display device 1 according to an embodiment may comprise a chassis assembly (e.g., the front chassis 30, the middle mold 40, the rear chassis 50), a display panel 10 disposed on the chassis assembly, at least one circuit board assembly 80 electrically connected to the display panel 10, and at least one cable 100, 100-1, 100-2, 100-3 for electrical connection with the display panel 10 and/or the circuit board assembly 80. The cable 100, 100-1, 100-2, 100-3 may include a cable body 110 including a connection terminal (e.g., the protective layer 114), and fixing portions 120, 120-1, 120-2, 120-3 at least partially cuttably connected to two opposite ends of the cable body 110. The fixing portions 120, 120-1, 120-2, 120-3 may include a fixing portion body 122 cuttably connected to the cable body 110 and including a fixing recess 1221, and a cutting portion 121, 121-1, 121-2 including a perforation line 1211 extending by a predetermined distance along a connecting portion between the fixing portion body 122 and the cable body 110. The fixing portion body 122 may be separable along the cutting portion 121, 121-1, 121-2 when the cable 100, 100-1, 100-2, 100-3 may be connected to the display panel 10 and/or the circuit board assembly 80.

According to an embodiment, the cutting portion 121, 121-1, 121-2 may include a dot-line perforation line (e.g., the perforation line 1211) extending in a width direction of the cable 100.

According to an embodiment, the cutting portion 121-1 may include a first perforation line 1211a extending in a width direction of the cable 100, a second perforation line 1211b extending in a width direction of the cable 100, and a cutting recess 1212 disposed between the first perforation line 1211a and the second perforation line 1211b.

According to an embodiment, the cutting portion 121-2 may include a first cutting recess 1213a, a second cutting recess 1213b, and a perforation line 1211 disposed between the first cutting recess 1213a and the second cutting recess 1213b. The first cutting recess 1213a may be open on one side, and the second cutting recess 1213b may be open one a side opposite to the one side of the first cutting recess 1213a.

According to an embodiment, a first fixing portion 120-3a may be at least partially cuttably connected to one end portion of the cable body 110, and a second fixing portion 120-3b may be at least partially cuttably connected to another end portion of the cable body 110. The first fixing portion 120-3a and the second fixing portion 120-3b may be disposed to be misaligned with each other and may include a dot-line perforation line (e.g., the perforation line 1211) extending along the width direction of the cable 100.

According to an embodiment, a sum of a width of the first fixing portion 120-3a and a width of the second fixing portion 120-3b may be substantially identical to a width of the cable 100.

According to an embodiment, an extension length of the first fixing portion 120-3a and an extension length of the second fixing portion 120-3b may be substantially identical.

According to an embodiment, the perforation line 1211 may be at least partially located between the connection terminal (e.g., the protective layer 114) and the fixing recess 1221.

According to an embodiment, the cable body 110 may include a base layer 111, at least one conductive line 112 disposed on one surface of the base layer 111, a cover layer 113 disposed on the base layer 111 to cover at least a portion of the at least one conductive line 112, and a reinforcement layer 115 disposed on a surface opposite to the one surface of the base layer 111.

According to an embodiment, the fixing portion 120, 120-1, 120-2, 120-3 may integrally extend from at least one from among the base layer 111, the at least one conductive line 112, the cover layer 113, and the reinforcement layer 115.

According to an embodiment, the cable 100, 100-1, 100-2, and 100-3 may be a flexible flat cable (FFC) or a flexible printed circuit board (FPCB).

A cable 100, 100-1, 100-2, 100-3 for electrical connection of an electronic component (e.g., the display panel 10 of FIG. 1 or the circuit board assembly 80 of FIG. 3) according to an embodiment may comprise a cable body 110 including a connection terminal (e.g., the protective layer 114), and a fixing portion 120, 120-1, 120-2, 120-3 at least partially cuttably connected to two opposite ends of the cable body 110. The fixing portion 120, 120-1, 120-2, 120-3 may include a fixing portion body 122 cuttably connected to the cable body 110 and including a fixing recess 1221, and a cutting portion 121, 121-1, 121-2 including a perforation line 1211 extending by a predetermined distance along a connecting portion between the fixing portion body 122 and the cable body 110. The fixing portion body 122 may be separable along the cutting portion 121, 121-1, 121-2 when the cable 100, 100-1, 100-2, 100-3 may be connected to the electronic component.

According to an embodiment, the cutting portion 121, 121-1, 121-2 may include a dot-line perforation line (e.g., the perforation line 1211) extending in a width direction of the cable 100.

According to an embodiment, the cutting portion 121-1 may include a first perforation line 1211a extending in a width direction of the cable 100, a second perforation line 1211b extending in a width direction of the cable 100, and a cutting recess 1212 disposed between the first perforation line 1211a and the second perforation line 1211b.

According to an embodiment, the cutting portion 121-2 may include a first cutting recess 1213a, a second cutting recess 1213b, and a perforation line 1211 disposed between the first cutting recess 1213a and the second cutting recess 1213b. The first cutting recess 1213a may be open on one side, and the second cutting recess 1213b may be open one a side opposite to the one side of the first cutting recess 1213a.

According to an embodiment, the cutting portion 121-3 may include a first fixing portion 120-3a at least partially cuttably connected to one end portion of the cable body 110, and a second fixing portion 120-3b at least partially cuttably connected to another end portion of the cable body 110. The first fixing portion 120-3a and the second fixing portion 120-3b may be disposed to be misaligned with each other and may include a dot-line perforation line (e.g., the perforation line 1211) extending along the width direction of the cable 100.

A method for manufacturing a display device 1 according to an embodiment may comprise at least one cable 100, 100-1, 100-2, 100-3 for electrical connection with an electronic component (e.g., the display panel 10 of FIG. 1 or the circuit board assembly 80 of FIG. 3) in the display device 1, and a cable tray 200, 200-1, 200-2, 200-3 for receiving the cable 100, 100-1, 100-2, 100-3. The cable 100, 100-1, 100-2, 100-3 may include a cable body 110 including a connection terminal (e.g., the protective layer 114), and fixing portions 120, 120-1, 120-2, 120-3 at least partially cuttably connected to two opposite ends of the cable body 110 and including at least one fixing recess 1221. The cable tray 200, 200-1, 200-2, 200-3 may include a tray body 210, and a pair of fixing protrusions 220 protruding from one surface of the tray body 210. The manufacturing method of the display device 1 may comprise an operation 1410 of loading the cable 100, 100-1, 100-2, 100-3 onto the cable tray 200, 200-1, 200-2, 200-3 by inserting the pair of fixing protrusions 220 into a fixing recess 1221 of each fixing portion 120, 120-1, 120-2, 120-3, an operation 1420 for separating at least a portion of the fixing portion 120, 120-1, 120-2, 120-3 of the cable 100, 100-1, 100-2, 100-3 loaded on the cable tray 200, 200-1, 200-2, 200-3 using a pickup device, and an operation 1430 of connecting the cable 100 where at least a portion of the fixing portion 120, 120-1, 120-2, 120-3 is separated to an electronic component of the display device 1.

According to an embodiment, the fixing protrusion 220-1 of the cable tray 200-1 may include an extension 221 protruding and extending from the tray body 210, and a stopper 222 bent to one side from the extension 221.

According to an embodiment, the pair of fixing protrusions 220-1 may be disposed to face each other.

According to an embodiment, the cable 100′ may include a bending portion 103 bent or folded at least once. The pair of fixing protrusions 220-2 may be disposed to be misaligned with each other.

According to an embodiment, the cable tray 200-3 may include a pair of guide ribs 211, 212 protruding from the tray body 210 to surround the bending portion 103 of the cable 100′.

What is claimed is:

1. A display device, comprising:
a chassis assembly;
a display panel on the chassis assembly;
a circuit board assembly electrically connected to the display panel; and
at least one cable configured to electrically connect the display panel or the circuit board assembly, and
wherein the at least one cable comprises:
a cable body comprising a connection terminal; and
a pair of fixing portions respectively connected to two opposite ends of the cable body and configured to be at least partially separated from the corresponding end of the cable body by cutting,
wherein each of the pair of fixing portions comprises:
a fixing portion body connected to the cable body and configured to be at least partially separated from the cable body by cutting, the fixing portion body including a fixing recess; and
a cutting portion including at least one perforation line extending by a predetermined distance along a connecting portion between the fixing portion body and the cable body, and
wherein the fixing portion body is separable from the cable body along the cutting portion in a case where the at least one cable is being connected to the display panel or the circuit board assembly.

2. The display device of claim 1, wherein the at least one perforation line extends in a width direction of the at least one cable.

3. The display device of claim 1, wherein the at least one perforation line comprises:
a first perforation line extending in a width direction of the at least one cable; and
a second perforation line extending in the width direction of the at least one cable, and
wherein the cutting portion further comprises a cutting recess between the first perforation line and the second perforation line.

4. The display device of claim 1, wherein the cutting portion further comprises:
a first cutting recess; and
a second cutting recess,
wherein the at least one perforation line is between the first cutting recess and the second cutting recess, and
wherein a side of the first cutting recess that faces away from the at least one perforation line is open, and a side of the second cutting recess that faces away from the at least one perforation line is open.

5. The display device of claim 1, wherein the pair of the fixing portions includes:
a first fixing portion connected to a first end of the cable body and configured to be at least partially separated from the first end of the cable body by cutting; and
a second fixing portion connected to a second end of the cable body opposite to the first end of the cable body and configured to be at least partially separated from the second end of the cable body by cutting, and
wherein the first fixing portion and the second fixing portion are disposed to be offset from each other in a longitudinal direction of the at least one cable.

6. The display device of claim 5, wherein a sum of a width of the first fixing portion and a width of the second fixing portion is equal to a width of the at least one cable.

7. The display device of claim 5, wherein a length of the first fixing portion in a length direction of the at least one cable is the same as a length of the second fixing portion in the length direction.

8. The display device of claim 1, wherein the at least one perforation line is at least partially between the connection terminal and the fixing recess.

9. The display device of claim 1, wherein the cable body comprises:
a base layer;
at least one conductive line on a first surface of the base layer;
a cover layer on at least a portion of the at least one conductive line, wherein at least the portion of the at least one conductive line is between the base layer and the cover layer; and
a reinforcement layer on a second surface of the base layer, opposite to the first surface.

10. The display device of claim 9, wherein the fixing portion extends from at least one from among the base layer, the at least one conductive line, the cover layer, and the reinforcement layer.

11. A cable for electrical connection of an electronic component, the cable comprising:
a cable body comprising a connection terminal; and
a pair of fixing portions respectively connected to two opposite ends of the cable body and configured to be at least partially separated from the corresponding end of the cable body by cutting,
wherein each of the fixing portions comprises:
a fixing portion body connected to the cable body and configured to be at least partially separated from the cable body by cutting, the fixing portion body including a fixing recess; and
a cutting portion including at least one perforation line extending by a predetermined distance along a connecting portion between the fixing portion body and the cable body,
wherein the fixing portion body is separable from the cable body along the cutting portion in a case where the cable is being connected to the electronic component.

12. The cable of claim 11, wherein the at least one perforation line extends in a width direction of the cable.

13. The cable of claim 11, wherein the at least one perforation line comprises:
a first perforation line extending in a width direction of the cable;
a second perforation line extending in the width direction of the cable; and
wherein the cutting portion further comprises a cutting recess between the first perforation line and the second perforation line.

14. The cable of claim 11, wherein the cutting portion further comprises:
a first cutting recess;
a second cutting recess; and
wherein the at least one perforation line is between the first cutting recess and the second cutting recess, and
wherein a side of the first cutting recess that faces away from the at least one perforation line is open, and a side of the second cutting recess that faces away from the at least one perforation line is open.

15. The cable of claim 11, wherein the pair of the fixing portion includes:
a first fixing portion connected to a first end of the cable body and configured to be at least partially separated from the first end of the cable body by cutting; and
a second fixing portion connected to a second end of the cable body opposite to the first end of the cable body and configured to be at least partially separated from the second end of the cable body by cutting, and
wherein the first fixing portion and the second fixing portion are disposed to be offset from each other in a longitudinal direction of the at least one cable.

16. A method for manufacturing a display device, the method comprising:
loading a cable onto a cable tray by:
inserting a first fixing protrusion of the cable tray into a first fixing recess of a first fixing portion of the cable, wherein the first fixing portion is connected to a first end of a cable body of the cable, and the first fixing portion is configured to be at least partially separated from the first end of the cable body by cutting; and
inserting a second fixing protrusion of the cable tray into a second fixing recess of a second fixing portion of the cable, wherein the second fixing portion is connected to a second end of the cable body of the cable, and the second fixing portion is configured to be at least partially separated from the second end of the cable body by cutting;
separating at least a portion of the first fixing portion or at least a portion of the second fixing portion of the cable loaded on the cable tray; and
connecting, after the separating at least the portion of the first fixing portion or at least the portion of the second fixing portion, the cable to an electronic component of the display device.

17. The method of claim 16, wherein the fixing protrusion of the cable tray includes:
an extension protruding from a tray body of the cable tray in a first direction; and
a stopper connected to the extension and extending from the extension in a second direction that crosses the first direction.

18. The method of claim 16, wherein the first fixing protrusion faces the second fixing protrusion.

19. The method of claim 16, wherein, while the cable is loaded on the cable tray, the cable includes a bending portion, and
wherein a rotational orientation of the first fixing portion is different from a rotational orientation of the second fixing portion.

20. The method of claim 19, wherein the cable tray further includes guide ribs that protrude from a tray body of the cable tray, wherein the guide ribs surround the bending portion of the cable.
